(19) United States
(12) Patent Application Publication
(10) Pub. No.: US 2007/0012423 A1
(43) Pub. Date: Jan. 18, 2007

(54) Liquid cooling jacket and liquid cooling device

(76) Inventors: Koichiro Kinoshita, Hadano (JP); Hironori Oikawa, Hadano (JP); Shigeo Ohashi, Tsuchiura (JP); Koichi Takahashi, Atsugi (JP); Takeshi Hizono, Yokohama (JP); Masato Nakanishi, Tokyo (JP)

Correspondence Address: MATTINGLY, STANGER, MALUR & BRUNDIDGE, P.C., 1800 DIAGONAL ROAD, SUITE 370, ALEXANDRIA, VA, 22314, US

(21) Appl. No.: 11/412,971

(22) Filed: Apr. 28, 2006

(30) Foreign Application Priority Data
Jul. 15, 2005 (JP) 2005-206314
Mar. 15, 2006 (JP) 2006-070158

(51) Int. Cl. H05K 7/20

(52) U.S. Cl. 165/80.4; 165/170; 165/185; 361/699; 257/722

(57) ABSTRACT

A heat receiving jacket in a liquid cooling device for electronic equipment, for transferring a heat from a heating portion in the electronic equipment to liquid refrigerant, is composed of a fin piece having a base portion formed thereon with thin fins which rise up from one surface of the base portion, being curved, and a casing accommodating therein the fin piece in its center part so as to cause the liquid refrigerant to flow between the thin fins. Further, the cooling device includes a plurality of heat receiving jackets and a plurality of heat radiating portions which are alternately connected so as to constitute a passage for the liquid refrigerant, a part of the passage being connected with a circulation pump so as to constitute a closed circulation passage for the liquid refrigerant. With this configuration, it is possible to provide a liquid cooling device capable of decreasing the temperature rise of a heating element such as a CPU, having a high performance and being excellent in costs.

### INCORPORATION BY REFERENCE

This application relates to and claims priority from Japanese Patent Application Nos. 2005-206314 filed on Jul. 15, 2005, and 2006-070158 filed on Mar. 15, 2006, the entire disclosure of which is incorporated herein by reference.

### BACKGROUND OF THE INVENTION

The present invention relates to a liquid cooling device which is appropriate for cooling a heating element such as a semiconductor integrated circuit element installed in any of various electronic equipment, for typical example, a personal computer or a server.

Electronic equipment typical one of which is a personal computer or a server incorporates, in its housing, a semiconductor integrated circuit element, as a heating element, which is representative of a CPU (Central Processing Unit) and the like. Thus, usually, cooling is indispensable in order to ensure normal operation of the heating element. These years, the computing speed of a CPU has been higher and higher, and as a result, the heating value has been further increased.

As a conventional cooling device for a CPU, there has been prosperously used an air cooling type one for blowing cooling air onto a heat sink from a fan attached to the heat sink or an equipment housing. However, as the packaging density of the equipment has become higher and higher, a space around the CPU has been further limited, resulting in limitation of the size of the heat sink, and accordingly, it is self-explanatory to limit the cooling capacity thereof. Further, since the size of the fan is also limited, it is required to rotate the fan at a high speed in order to deliver a large air volume, causing a problem of increased noise.

In addiction to the air cooling device as stated above, there has been used a liquid cooling device which can prevent its size from being substantially limited since a heat-exchanger may arranged at a position which can be selected without severe restraints, and accordingly, a cooling limit becomes higher than that of the air cooling device, and noise can be reduced. Thus, these years, liquid cooling devices have been more and more used for cooling a CPU or the like in an electronic equipment.

Meanwhile, an electronic equipment such as a personal computer or a server incorporates therein not less than two CPUs as necessary, in order to ensure higher performance and safe operation of the electronic equipment upon occurrence of a failure of one of the CPUs. For example, JP-A-5-315488 discloses a liquid cooling device for an electronic equipment incorporating therein not less than two CPUs, as an example of prior art. In the configuration disclosed in the JP-A-5-315488, liquid refrigerant fed by a pump from a container for reserving the liquid refrigerant is led through a jacket connected to an upstream side CPU by way of a pipe line, so as to absorb heat from an integrated circuit, and the liquid refrigerant having passed through the upstream side jacket, is then fed into a jacket connected to another downstream integrated circuit. The liquid refrigerant is led through the downstream integrated circuit so as to absorb heat from the integrated circuit, and then it radiates the heat to the ambient air through a heat-exchanger. The liquid refrigerant from which the heat is absorbed so as to lower its temperature is returned to the pump for circulation through the cooling device for cooling a plurality of integrated circuits.

Further, for example, JP-A-2002-372360 discloses such a configuration that liquid coolant fed by a pump distributed into two jackets in parallel by way of two branch tubes so as to absorb heat from CPUs which are connected respectively to the two jackets, and thereafter, is merged from outlets of the two jackets into a radiator where the heat is radiated to the ambient air.

JP-A-2005-100091 discloses, as another example, a liquid cooling device which is composed of a jacket, a pump, a tank and a radiator, in the form of a single unit, and which is connected to a CPU, for cooling the associated one of CPUs.

Further, for example, JP-A-6-266474 discloses a liquid cooling device which enables a heat-exchanger to be arranged at a position which can be selected without serious restraint and without serious limitation to the size of the cooling device, and accordingly, the limitation to the cooling capacity becomes larger than that of an air-cooling device enhanced while the noise can be reduced. Thus, these years, liquid coolly devices have been more and more used for cooling CPUs or the like in electronic equipment.

In the case of using a liquid coolly device in an electronic equipment such as a personal computer or a server, it is in particular important to enhance the performance of a heat-exchanger (jacket) which is connected to a heating element such as a CPU, for transferring a heat from the heating element to liquid refrigerant. A prior art jacket is disclosed in, for example, JP-A-2003-152376 which discloses a jacket having such a configuration that a metal pipe line formed in a loop-like shape is joined to a metal base plate in order to constitute a passage configuration of the jacket.

Further, JP-A-2005-166855 discloses an example in which a plurality of metal plates each formed therein slits are stacked one upon another, the slits being used to define liquid channels.

### SUMMARY OF THE INVENTION

These years, the heating value of a heating element in a CPU or the like incorporated in an electronic device such as a personal computer or a servers has been increased more and more since the computation speed has been increased while the performance thereof has been enhanced. In order to operate a high performance electronic equipment for a long time with a high degree of reliability, it is required to restrain a temperature rise of the heating element. Accordingly, there have been caused the following problems:

In order to enhance the performance of the heat-exchanger (jacket), it is desirable to increase the surface area of a liquid channel as possible as it can. Thus, in the case of using, for example, a metal pipe for a liquid channel in the jacket, the metal pipe is formed in a loop-like shape so as to prolong the length of the metal pipe in order to increase the surface area. However, the longer the metal pipe, the higher the flow resistance, a pump having a larger capacity is required. Further, in the case of, for example, slit plates stacked one upon another, so many slits have to be formed in each of thin plates in order to increase the surface area, and further, these thin plates have to be all joined to one another. As a result, the manufacturing costs would be excessively increased.

Further, in the case of liquid refrigerant flowing successively through an upstream jacket and a downstream jacket in a cooling device for cooling a plurality of CPUs, since liquid refrigerant whose temperature is increased by a heat absorbed into an upstream heat-exchanger, flows into a jacket mounted to a downstream CPU, there is caused such a problem that the temperature of the downstream CPU is increased by a value corresponding to an increase in the temperature of the liquid refrigerant.

Further, in the case of two jackets into which liquid refrigerant flows being distributed, in a cooling device for cooling a plurality of CPUs, a flow rate for each of jackets is decreased, and accordingly, there has been raised such a problem that the temperature rise of each of the CPUs becomes larger. Further, as to liquid channel devices for the jackets after branching, the allocation of flow rates to the respective jackets becomes different from one another due to balance in pressure loss caused by, for example, a difference between the lengths of tubes, and accordingly, there has been raised such a problem that the temperature of one of the CPUs becomes larger that of the other CPU.

Further, in the case of liquid cooling devices which are mounted respectively to several CPUs in a cooling device for cooling them, if a plurality of CPUs have to be respectively cooled, the respective numbers of components including pumps, tanks, radiators and the like have to be equal to that of the CPUs, resulting in increased costs.

Thus, the present invention is devised in view of the above-mentioned problems inherent to prior art as stated above, and, accordingly, an object of the present invention is to provide a cooling device for an electronic equipment in which a CPU generates a high temperature heat, having a high performance and cost effective jacket for restraining a temperature of a heating element such as the CPU from increasing.

To the end, according to the present invention, there is provided a cooling device for an electronic equipment, comprising a first heat-exchanger for receiving a heat generated from a heating element, liquid refrigerant for transferring the received heat, a second heat-exchanger for radiating the heat transferred by the liquid refrigerant, and pipe line members arranged between the first heat-exchanger and the second heat-exchanger, for circulating the liquid refrigerant therebetween, wherein one or each of the heat-exchangers is composed of a sealed frame for passing therethrough the liquid refrigerant, and a passing member composed of a plurality of channel wall pieces arranged in parallel with one another within the frame, for diving and passing therethrough the liquid refrigerant, the heat-exchangers being formed in their side walls with flow inlets into which the liquid refrigerant flows, and flow outlets from which the liquid refrigerant flows out, the flow inlets and flow outlets being connected therebetween by the above-mentioned pipe line members, the frame being provided therein with header portions serving as spaces for dividing and merging the liquid refrigerant between the flow inlets, the flow outlets and the passing member, the channel wall pieces of the passage member having wall surfaces which are arranged in parallel with one another and which are curved in order to increase surface areas making into contact with the liquid refrigerant.

Further, a width of a lattice of channel wall pieces which are arranged in parallel with one another therein, is larger than that of the header portions defining the spaces for dividing the liquid refrigerant, and provided in the frame.

Further, in the cooling device for electronic equipment according to the present invention, the passing member is composed of the channel wall pieces and a base member, and the passage wall pieces are formed by a caving process in which the base member is carved, so as to be integrally incorporated with the base member.

Further, to the end, according to the present invention, there is provided a cooling device for an electronic equipment comprising a plurality of jackets each formed therein with liquid channels, for receiving a heat from a heating member, a pump for driving liquid refrigerant, a radiator having channels therein, for radiating a heat from the liquid refrigerant, and pipe line members connecting among the jackets, the pump, the radiator so as to form a closed circulation passages the radiator having a plurality of liquid channels which are independent from one another, each of the plurality of liquid channels which are independent from one another having an inlet and an outlet for the liquid refrigerant, the plurality of jackets having inlets and outlets connected respectively to the liquid channels therein, the closed circulation passage being connected alternately to the liquid passages in the jackets and the plurality of liquid passages in the radiator in series, and the pump being provided in the closed circulation passage.

Further, according to the present invention, the cooling device for electronic equipment comprises two jackets consisting of a first jacket and a second jacket, and the radiator is integrally formed having two liquid passages independent from each other.

Further, according to the present invention, the cooling device for electronic equipment, wherein an axial flow fan is provided, being opposed to the radiator, the liquid channels which are connected to the liquid inlets of the separated liquid passages in the radiator, being located at one end side of the radiator.

Further, according to the present invention, there is provided a cooling device for an electronic equipment, a plurality of jackets each having therein liquid passages, and connected respectively to a plurality of semiconductor elements mounted in the electronic equipment, a pump for driving liquid refrigerant, a radiator portion having therein liquid channels, for radiating a heat from the liquid refrigerant, pipe line members connecting among the jacket, the pump and the radiator portion, the radiator portion being composed of a plurality of radiators in which liquid channels are independent from one another, each of the liquid channels in the respective one of the radiators being provided with an inlet and an outlet for the liquid refrigerant, the respective radiator liquid channels and the respective jackets are alternately connected in series so as to form a closed circulation passage, and the pump being incorporated in the closed circulation passage so as to circulate the liquid refrigerant.

With the configuration as stated above, there may be provided a cooling device having a high-performance and cost-effective heat-exchanger (jacket) for restraining the temperature of a heating element such as a CPU installed in an electronic equipment and generating a high temperature heat, to a small value.

Other objects, features and advantages of the invention will become apparent from the following description of the embodiments of the invention taken in conjunction with the accompanying drawings.

### BRIEF DESCRIPTION OF THE DRAWINGS

FIG. 1 is a front view illustrating an overall configuration of a cooling device for electronic equipment in an embodiment of the present invention;

FIG. 2 is a side view illustrating the cooling device for electronic equipment shown in FIG. 1;

FIG. 3 is a perspective view illustrating an overall configuration of a cooling device for electronic equipment in another embodiment of the present invention;

FIG. 4 is an exploded perspective view illustrating a jacket constituting the liquid cooling device for electronic equipment;

FIG. 5 is a sectional view along line V-V in FIG. 4;

FIG. 6 is a sectional view illustrating a top surface of the jacket shown in FIG. 4;

FIG. 7 is a sidewise sectional view illustrating a fin piece constituting the jacket shown in FIG. 4;

FIG. 8 is an exploded perspective view illustrating a jacket constituting a cooling device for electronic equipment in further another embodiment of the present invention;

FIG. 9 is a sectional view along line IX-IX in FIG. 8;

FIG. 10 is an exploded perspective view illustrating a jacket constituting a cooling device for electronic equipment in another embodiment of the present invention;

FIG. 11 is a sectional view along line XI-XI in FIG. 10;

FIG. 12 is a section view illustrating a top part of the jacket constituting the cooling device for electronic equipment in the other embodiment of the present invention;

FIG. 13 is an exploded perspective view illustrating a jacket constituting the cooling device for electronic equipment in another embodiment of the present invention;

FIG. 14 is a sectional view along line XIV-XIV in FIG. 13;

FIG. 15 is a view illustrating a configuration of a pipe line in a cooling device according to the present invention; and

FIG. 16 is a view for explaining the advantages of the present invention.

### DESCRIPTION OF THE PREFERRED EMBODIMENTS

Explanation will be hereinbelow made of embodiments of the present invention with reference to the accompanying drawings.

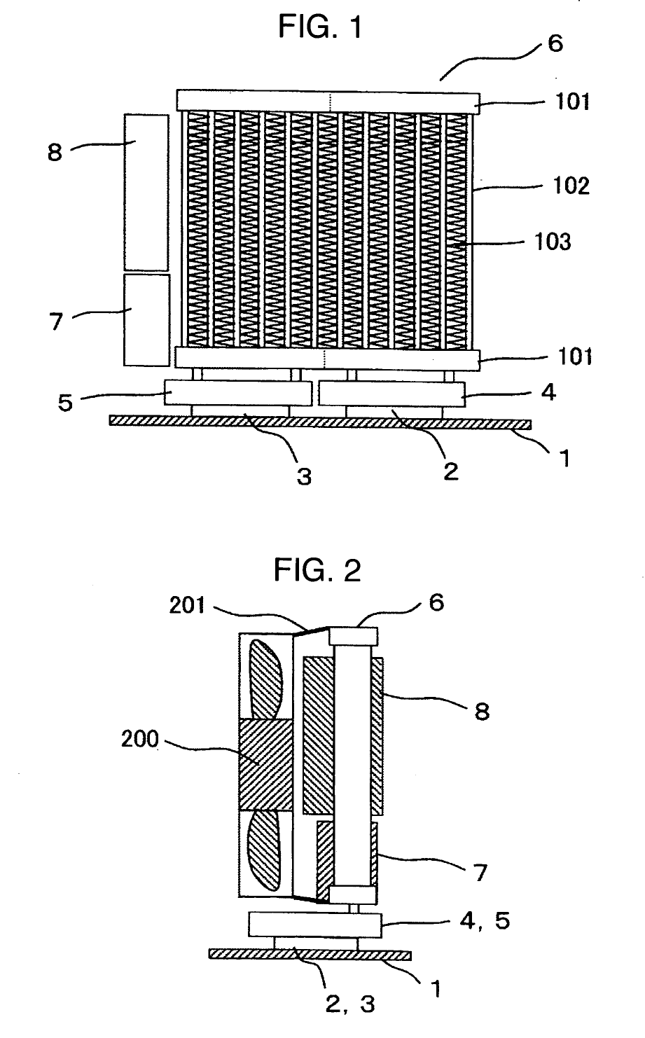

At first, referring to FIGS. 1 and 2 which show an overall configuration of a cooling device in an embodiment of the present invention, which may effectively cool two heating elements (for example, CPUs) that are incorporated in a housing of an electronic equipment such as a personal computer, a server or the like, by circulating liquid refrigerant. FIGS. 1 and 2 are a front view and a side view illustrating the liquid cooling device incorporated in the electronic equipment.

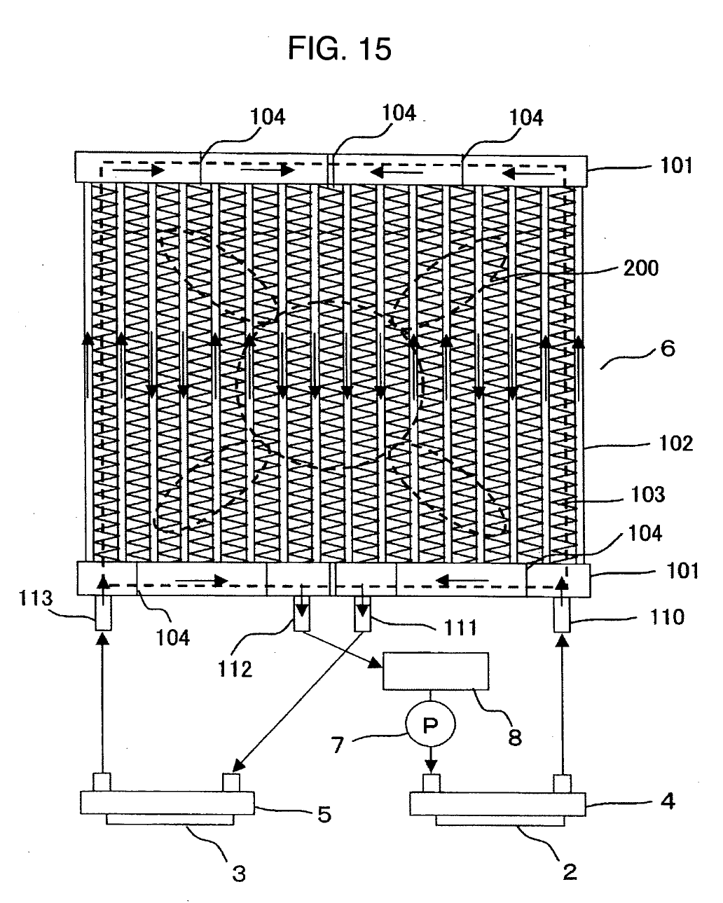

The liquid cooling device is composed of two CPUs 2, 3 mounted on a circuit board 1, first and second jackets 4, 5 connected respectively to the CPUs, a radiator 6, a circulation pump 7 and a refrigerant tank 8. Liquid refrigerant enclosed in the liquid cooling device is circulated through the jackets 4, 5 and the radiator 6 by the circulation pump 7. At this time, the liquid refrigerant radiates a heat from the CPUs 2, 3 which is received by the jackets 4, 5, through the intermediary of the radiator. It is noted that pipe lines and the like connected to the components are not shown in FIGS. 1 and 2. The pipe lines will be detailed later with reference to FIG. 15.

As shown in FIG. 1, the radiator is provided therein with pipe lines 102 between a pair of headers 101, 101 which are arranged being spaced and opposed to each other in a vertical direction. The pipe lines are made of materials having a high thermal conductivity, for example, metal such as copper or aluminum. Further, the plurality of the pipe lines 102 are arranged in parallel with one another at equal intervals, and are connected to one another. Further, between the pipe lines 102, corrugated fins 103 which are also made of materials having a high thermal conductivity, for example, metal such as copper or aluminum, are attached. Further, as shown in FIG. 2, the radiator 6 is incorporated at its one surface with the so-called axial flow fan 200. It is noted that a duct 201 for connecting the radiator 6 and the axial flow fan 201 with each other at their outer peripheral parts is provided therebetween.

According to the present invention, the circulation pump 7 for liquid refrigerant and the refrigerant tank 8 constitute a part of the liquid cooling device. It is noted that the circulation pump 7 drives the liquid refrigerant in the liquid cooling device, for circulating the liquid refrigerant through a loop in the cooling device. Meanwhile, the refrigerant tank 8 reserves therein the liquid refrigerant (for example, pure water, water mixed with the so-called antifreezing fluid such as propylene glycol at a predetermined rate, or the like) by a quantity sufficient for maintaining a required cooling performance of the cooling device over a product guarantee period of, for example, 5 years, taking possible external leakage of the liquid refrigerant in to consideration.

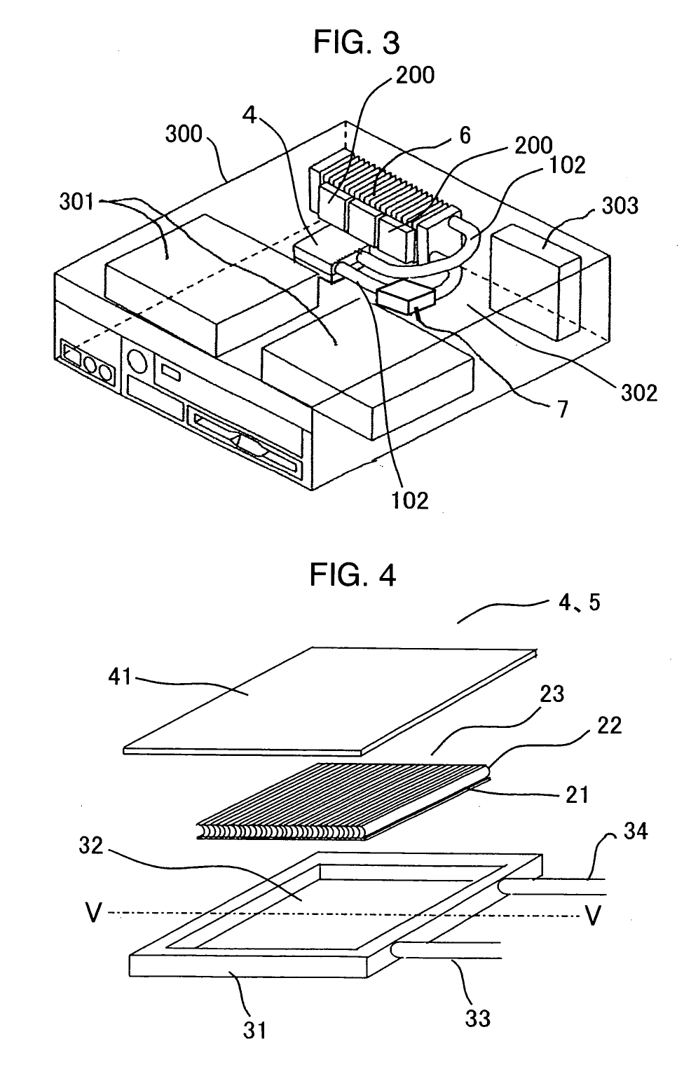

FIG. 3 shows a cooling device in another embodiment of the present invention which is used in an electronic equipment. In this embodiment, the cooling device is applied in the body portion of, for example, a desk-top type personal computer. The desk-top type personal computer has, in its body portion, a housing 300 made of a metal sheet formed into a parallelepiped shape. The housing 300 is incorporated therein with various drive units 301 for driving external data recording mediums including a disc, a CD and a DVD and a storage unit consisting of a hard disc unit. Meanwhile, an electronic circuit portion 302 incorporating the cooling device according to the present invention is arranged on the rear surface side of the housing 300. Further, there is shown, in FIG. 3, an electric power source 301 for feeding a desired electric power to each of components including the drive units 301 and the electronic circuit portion 302, from a commercial power source. The electronic circuit portion 302 is mounted thereon with a heating element such as a CPU as a main component. It is noted that a chip for the CPU as the heating element is mounted being made into direct contact with the lower surface side of the jacket 4 stated above, and accordingly, it is not shown in FIG. 3. Further, the electronic circuit portion 302 also includes the jacket 4 connected to the CPU, for receiving a heat generated from the CPU, the radiator 6 for radiating a heat from the CPU, outside of the electronic equipment, the circular pump 7. The components constituting a thermal cycle are connected thereto with passages for feeding liquid refrigerant (for example, pure water or water mixed with the so-called antifreezing fluid such as propylene glycol at a predetermined rate) to the components, such as, for example, tubes (pipe lines) 102 made of, for example, metal or an elastic material such as rubber. Further, the radiator 6 is provided with a planar fan 200 (in this embodiment, a plurality of fans, for example, three fans) for blowing air onto the several fines as components of the radiator 6 so as to forcibly radiate the heat transferred from the jacket 4.

Referring to FIG. 4 which shows an example of the jacket used in this embodiment, the jacket has a fin piece 23 which is composed of a metal panel (fin base portion) 21 made of for example, copper having excellent thermal conductivity, and several fines 22 formed in the former, and which is fitted in a jacket casing 31 having a height adjusted to the height of the fin piece 23 and defining therein a recess 32. Thereafter, the jacket casing 31 is covered thereover with a fitting cover 41. The fin pieces 23 is formed by carving the surface of the metal plate 21 at fine pitch, successively from one end thereof so as to relive the several fins. This carving process is effective for forming liquid channels at fine pitches. The jacket casing 31 is formed therein with an inlet port 33 and an outlet port 34 for the liquid refrigerant. The jacket casing 31 and the base portion 21 of the fin piece 23, and the jacket casing 31 and the cover 41 are joined together by brazing.

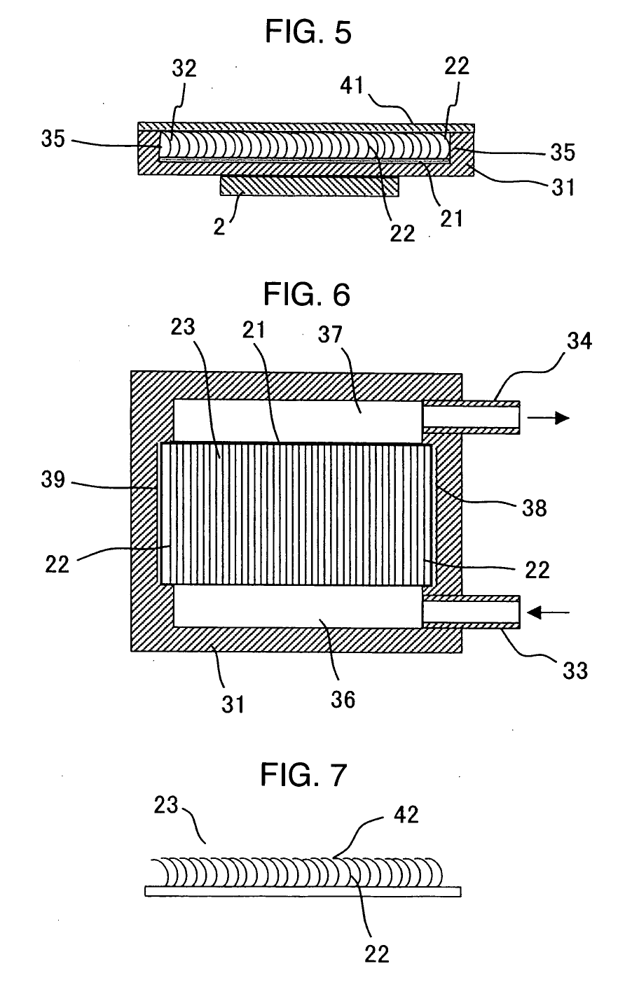

Next, detailed explanation will be made of the jacket in this embodiment with reference to FIGS. 5 and 6, and FIG. 5 is a sectional view illustrating the jacket configured as shown in FIG. 4. The fin piece 23 is designed under dimensional control so that gaps defined between the tip ends of the fins and the cover 41 and gaps between the fins 22 and the inner side surface 35 of the jacket casing 31 at opposite ends of the fin base portion 21 are set to be not greater than the width of each of the liquid channels, that is, the pitches of the fins, in order to prevent the liquid refrigerant from passing through those parts which are other than those between the fines, or passing the liquid channels between the fins. The CPU 2 is made contact with the outer surface of the jacket casing 31 through the intermediary of heat-conductive grease. In order to efficiently transfer a heat generated from the CPU 2 to the liquid refrigerant which flows through the liquid channels between the fines 22, it is desirable to join the jacket casing 31 and the fin base portion 21 of the fin piece 23 to each other by brazing or the like so that their joined surfaces are completely made into close metal-to-metal contact with each other.

FIG. 6 is a sectional view illustrating the top surface of the inside of the jacket. The inlet ports 33 and the outlet port 34 for the liquid refrigerant are formed by piercing one side surface of the jacket casing 31 with, for example, two pipes. Space portions (header portions) 36, 37 communicated respectively with the inlet port 33 and outlet ports 34 are provided upstream and downstream of the fin piece 23. The header portions 36, 37 define buffer zones for distributing the liquid refrigerant flowing thereinto from the inlet port 33, uniformly among the fins (liquid channels) formed in the fin piece 33.

Further, the jacket casing 31 is formed in its inner surface with recesses 38, 39 which receive end parts of the fin base portion 23. That is, the width of the lattice of fines which are arranged in parallel with each other, is greater than the width (in a direction perpendicular to the longitudinal direction of the liquid channels among the fins and parallel with the surface of the figure) of the header portion 36. If the width of the lattice of the fins is greater than the width of the inter-fin inflow part of the header portion on the side where the liquid refrigerant flows into, there may be used such a structure that protrusions are formed on the inner surface of the jacket casing 31.

With the configuration as stated above, the liquid refrigerant may be prevented from bypassing the liquid channels and flowing through the gaps defined between the fins 22 formed on the outermost ends of the fin base portion 21 and the inner surface of the jacket casing 31, and further, the positioning of the fin piece 23 when it being joined to the jacket casing may be facilitated. Since the fin surfaces are possibly curved during the formation of the fin fins, the gaps defined between the fins formed at the outermost ends of the fin base portion 21 and the inner surface of the jacket casing 31 becomes inevitably larger. Thus, as stated above, the fitting of the fin base portion 21 in the recesses formed in the inner surface of the jacket casing 31 may exhibit a relative effect for preventing the liquid refrigerant from bypassing the liquid channels among the fins.

Similarly, no gaps between the tip ends of the fins and the inner surface of the cover are also desirable. Should the heights of the tip ends of the fins be uneven, the heightwise position of the cover would be determined by the highest fins, and accordingly, gaps would be defined between the lower fines and the cover, resulting in bypassing of the liquid refrigerant. Thus, it may be considered that the tip ends of the fines are pressed against and then brazed to the cover by applying a load to the cover. Since the fins have curved shapes, the respective fins may be readily deformed heightwise. Thus, since all fins are curved, the tip ends of the fins may be readily made into contact with the cover, thereby it is possible to offer a remarkable effects for preventing the liquid refrigerant from bypassing the liquid channels and flowing through the gaps between the tip ends of the fins and the cover.

Further, as shown in FIG. 7, the tip ends of the fins may be bent down or the curvatures of the tip ends of the fins may be set to be larger so that the fins adjacent to each other are made into contact with each other at their tip ends. With this configuration, it is possible to prevent the gaps from being defined between the tip ends of the fins and the cover when the fin pieces 21, the jacket casing 31 and the cover 41 are joined to one another. As a result, the cover 41 and the tip ends of the fins 22 may be thermally connected with each other, and accordingly, the heat condition can be made from the cover 41 to the fins 22, in addiction to the heat conduction from the fin base portion 21 to the fins 22, thereby it is possible to enhance the capacity of heat conduction to the fins 22, and also to enhance the capacity of the heat conduction to the liquid refrigerant.

Further, a brazing filler may be set between the tip ends of the fins and the cover so as to completely eliminate the gaps therebetween in order to prevent the liquid refrigerant from bypassing the liquid channels and to effect heat condition.

Explanation will be hereinbelow made of a jacket in another embodiment of the present invention, which may also combined with the structure for preventing the liquid refrigerant from bypassing the liquid channels, as stated above.

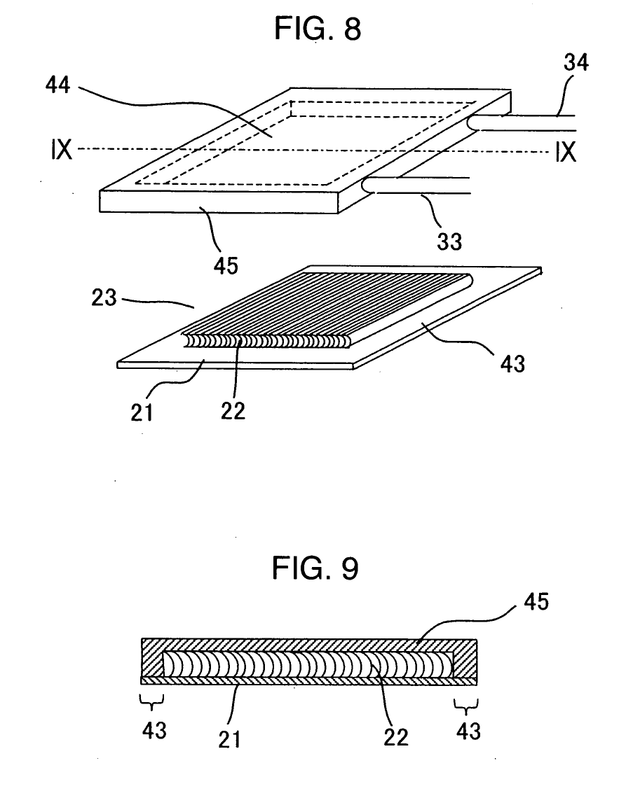

FIG. 8 shows another embodiment of the jacket according to the present invention. In the embodiment of the jacket shown in FIG. 4, the fin base portion of the fin piece should be surely brazed to the bottom surface of the jacket casing so as to cause the joined surfaces to be completely made into close contact with each other in order to efficiently transfer a heat generated from a heating element such as a CPU to the liquid refrigerant flowing through the liquid channels between the fins. However, the larger the areas of the joined surfaces, the higher the possibility of incomplete joint, the heat resistance would be increased. In view of this point, in this embodiment shown in FIG. 8, the CPU and the fin base portion are made into direct contact with each other.

In the fin piece 23 of the jacket in this embodiment, the fin base portion 23 is carved so as to relieve curved fins 22, leaving a peripheral flange part 43 without forming the fins 22. Further, the jacket are formed with an inlet port 33 and an outlet port 34 for the liquid refrigerant, and a cover 45 is formed in its center part with a recess 44 adjusted to the height of the fins 22. The flange part 43 of the fin piece 23 is joined to the cover 45 by brazing or the like.

In order to form the flange part 43, there may be used any of various methods, such as a method of removing the peripheral part of the fin piece 23 after the fins 22 are formed on the overall surface of the fin piece 23, or a method comprising the steps of preparing the fin base portion 21 previously formed in its center part thereof with a protrusion, and carving the protrusion so as to relieve the curved fins 22.

As shown in FIG. 9 which is a sectional view, the peripheral part of the cover 45 and the flange part 43 of the fin piece are joined to each other so as to define liquid channels between the curves fins and the recess 44 of the cover 45. In this embodiment, it may be sufficient if air-tightness is held in the joined part between the cover 45 and the flange part 43 of the fin piece 23 in order to ensure the thermal connection with a low thermal resistance from the CPU to the fin base 23. Moreover since it is sufficient to provide a gas-tight joint between the cover 45 and the flange part 43, there may be used a sealing structure with the use of an O-ring seal or the like, in addition to the brazing.

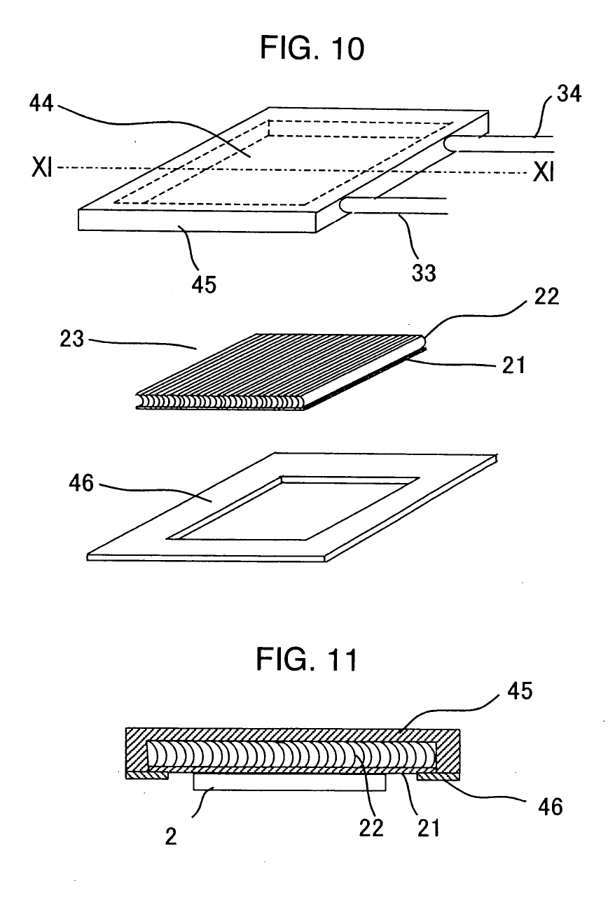

Further, in another similar method, a configuration shown in FIGS. 10 and 11 may be used. In this embodiment, in view of the previous embodiment shown in FIGS. 8 and 9, there may be similar technical effects and advantages with no flange part being formed in the fin piece. This configuration is the same as that shown in FIGS. 8 and 9, except that a frame having an opening larger than the external shape of a CPU 2 is prepared so as to allow the frame 46 to have a function similar to that of the flange part 43 of the fin piece 23 (Refer to FIGS. 8 and 9).

Referring to FIG. 11 which is a sectional view, the cover 45 and the peripheral part of the fin base portion 21 where no fins are formed are joined to each other by the frame 46 simultaneously in a gas-tight manner, and accordingly, the frame 46 exhibits a function which is similar to that of the flange part 43 of the fin piece in the previous embodiment (FIGS. 8 and 9). Thus, the thermal connection from the CPU 2 to the fin base 21 can be ensured with a low heat resistance without the provision of the flange part in the fin piece 23.

The fin piece 23 may be the same as that explained in the embodiment shown in FIG. 4. In the case of using a method of forming fins on the overall surface of the fine base portion as in the previous embodiment (FIGS. 8 and 9), and thereafter removing the fins in the peripheral part of the fin base portion, it is required to prevent channels between the fins from being blocked due to burrs, warps or the like. On the contrary, in this embodiment, no process steps are required after the formation of the fins, and it is possible to eliminate the necessity of taking a care of preventing occurrence of blockage of channels between the fins, thereby the constraint to the manufacture of the fin piece 23 can be reduced.

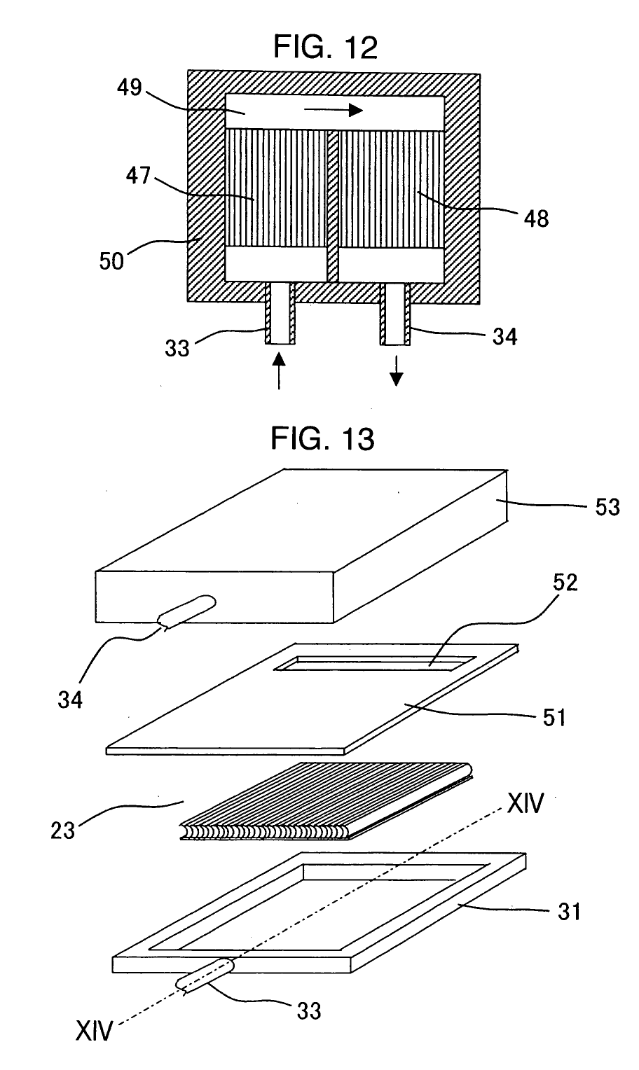

Referring to FIG. 12 which shows a channel configuration in another embodiment of the present invention, after the preparation of a plurality of fin pieces (for example, two fin pieces as shown in FIG. 12) 47, 48 in which curved fins are formed in relief by carving, the fin pieces are set in a recess 49 which is formed in a jacket casing 49 having a height adjusted to that of the fin pieces 47, 48 and which is locally partitioned, the channels formed in the fin pieces being connected in series (the flowing direction of liquid refrigerant is indicated by the arrows), and are then jointed to the latter. In this embodiment, the flowing speed of the liquid refrigerant may be increased, and unevenness of flow rates among the liquid channels may be reduced in comparison with that of the previous embodiment in which only one fin piece is used, under such a condition that the number of fins, the area of the fins and the overall liquid flow rate are set to be equal therebetween, thereby it is possible to further enhance the cooling effect.

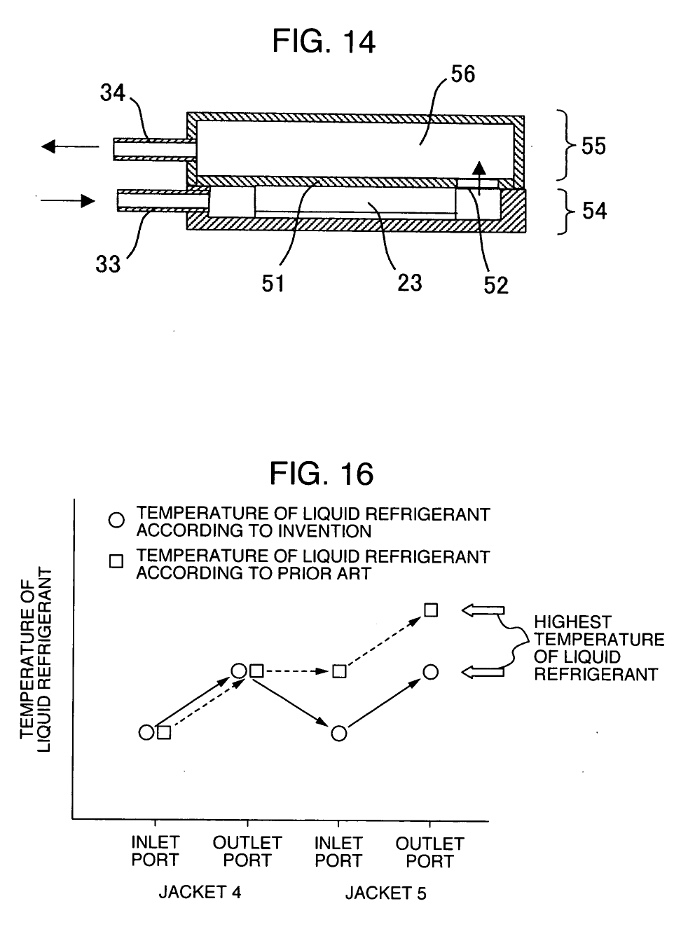

Referring to FIGS. 13 and 14 which show further another embodiment, this embodiment has a configuration similar to that of the previous embodiment (as shown FIG. 4), except that a partition panel for partitioning the inside of the jacket in the thicknesswise direction is provided, that is, the jacket is composed of a jacket casing 31 for accommodating therein a fin piece 23, a cover 53 formed therein with a recess, and the partition panel 51 formed therein an opening.

As show in FIG. 14 which is a sectional view, the partition panel 51 partitions the inside of the jacket into a zone 54 where the fin piece 23 is provided, and a zone 55 for reserving therein the liquid refrigerant, both zones being communicated with each other through the opening 52 formed in the partition panel 51. The liquid reserving zone 55 is defined by the cover 53 formed therein with the recess. The zones 54, 55 are communicated respectively with a liquid inlet port 33 and a liquid outlet port 34 which are fitted respectively to the jacket casing 31 and the cover 53. The content volume of the liquid reserving zone 55 is set to a value by which the cooling device may be operated over a service life of a product incorporating the cooling device, taking consideration with replenishment of the liquid refrigerant for leakage. That is, the liquid reserving zone has the same function as that of the so-called reserving tank. It may be said that the jacket in this embodiment is integrally incorporated with the reserving tank.

Although explanation has been made of the embodiments in which the curved fin pins formed in relief by carving are used in the jacket for receiving a heat generated from the CPU, they may be used for a liquid channel portion on the heat radiating portion (radiator) side for radiating a heat from the liquid refrigerant into the ambient air. That is, for example, the liquid channel portion on the heat radiating portion side is formed so as to have a configuration similar to that of the jacket shown in FIG. 4, and further, fins for exchanging a heat with the air are formed on the outer surface of a cover of the radiator.

Referring to FIG. 15, detailed explanation will be made of the configuration of the radiator and the pipe lines. The arrows in FIG. 15 indicate the flowing directions of the refrigerant. In the radiator, the liquid channels through which the liquid refrigerant flows are split at the center of the radiator into two radiator zones which are provided thereto with inlet ports 110, 113 and outlet ports 111, 112 for the liquid refrigerant, respectively. In each of the split radiator zones, the liquid channels are grouped into several units between headers 101 by means of partitions wall 104s which therefore partitions the inside headers 101 into a plurality of compartments, each unit including two upward flow pipe lines 102 in parallel and two downward flow pipe lines 102 in parallel which are connected respectively to the upward flow pipe lines 102 in series.

The liquid discharged from the pump 7 is circulated through the pipe line tubes which connect the components there among in the liquid cooling device. The pipe line tubes may be in general made of metal, but in the case of pipe lines which are possibly moved (in such a case that two CPUs are to be cooled, the jackets connected to these CPUs for cooling them, are preferably movable due to height difference between the CPUs and in view of the working efficiency), the movable parts of the pipe lines may be made of elastic materials such as butyl rubber which is less permeable with respect to the liquid refrigerant, through their wall surfaces.

The liquid refrigerant discharged from the circulation pump 7 flows through the first jacket 4 connected to the CPU 2 so as to absorb a heat from the CPU 2, and then flows into the first zone of the radiator 6 (on the right side of FIG. 15) from the inlet port 110 provided to one end side of the radiator 6, and accordingly, the heat is radiated from the first zone of the radiator 6. The liquid refrigerant from which the heat has been radiated and the temperature of which has been therefore lowered, then flows from the outlet port 111 into the second jacket 5 connected to a CPU 3.

The liquid refrigerant having passed through the jacket 5 so as to absorb a heat from the CPU 3 flows into the second zone of the radiator 6 from the inlet port 113 provided to the one end side of the radiator 6 so as to radiate the heat from the second zone of the radiator. The liquid refrigerant from which the heat is radiated in the second zone and the temperature of which has been lowered, flows out from the outlet port 112 so as to be returned into the circulation pump 7 by way of the refrigerant tank 8. Then, the liquid refrigerant is again circulated through the liquid cooling device for cooling the CPUs 2, 3. The axial flow fan 200 is arranged at the center of the radiator 6, having an outer peripheral zone in which the air speed is highest is aligned with the liquid channels which are communicated with the inlet port 110 and the outlet port 113 and which are arranged outermost of the radiator so as to pass therethrough the refrigerant having a highest temperature, isolating from the liquid channels communicated with the inlet ports 111 and the outlet port 112.

With the configuration as stated above, the liquid refrigerant having absorbed a heat from the CPU 4 through the intermediary of the first jacket 4 radiates the heat once in the radiator 6, and thereafter flows in the second jacket 5. Thus, the temperature rise of the liquid refrigerant by the CPU 2 is absorbed through the radiation by the radiator so that the temperature of the liquid refrigerant is lowered down to the temperature at the time of flowing into the first jacket 4. Thus, the temperature of the liquid refrigerant flowing into the second jacket 5 becomes equal to that flowing into the first jacket 4, that is, the temperature of the upstream CPU 2 may be prevented from affecting the temperature of the downstream CPU 3.

The temperature relationship as stated above is shown in FIG. 16. In comparison with a conventional cooling device in which jackets are connected to each other in series similar to that stated above, the temperature relationship between the jacket 4 and the liquid refrigerant flowing therethrough is the same as that between the jacket 5 and the liquid refrigerant, and accordingly, the CPUs 2 and 3 connected to the jackets 4, 5 may be uniformly and efficiently cooled down. As similarly shown in FIG. 7, according to the present invention, the highest temperature of the liquid refrigerant may be lowered. This fact greatly influence upon factors which affect the longtime reliability of the cooling device in view of the penetration of the liquid refrigerant from the pipe lines, and corrosion. That is, the higher the temperature of the liquid refrigerant, the more remarkable the progress of penetration and corrosion, it is extremely, effective. The lowering of the highest temperature of the liquid refrigerant is extremely effective for obtaining a high degree of reliability over a longtime period.

Further, all of the components of the cooling device are connected in series in view of the flowing passage for the liquid refrigerant, that is, no branching are present therefor. Thus, there may be prevented occurrence of lowering of the flow rate of the liquid refrigerant per jacket, which caused by allocation of the flow of the liquid refrigerant, and flow rate difference between the two jackets.

Further, as to the liquid channels in the radiator having two split zones, the liquid channels where the high temperature liquid refrigerant flows is isolated from the liquid flow channels where the heat has been radiated from the liquid refrigerant and the temperature thereof has been lowered, and accordingly, the liquid refrigerant whose temperature has been lowered is prevented from being affected by the high temperature liquid refrigerant. Thus, it is possible to prevent the temperature of the liquid refrigerant flowing into the jacket from being increased, that is, it is possible to prevent the jacket from lowering its heat absorbing performance. In particular, since the liquid channels through which the highest temperature liquid refrigerant flows are arranged at the outer most ends of the radiator, the supply zone of the axial flow fan where the cooling air speed is highest is aligned with the zones of the liquid channels where the high temperature liquid refrigerant flows, and accordingly, efficient heat-exchange may be carried out between the liquid refrigerant and the cooling air.

Further with the configuration in which the liquid channels are split into two zones, and in which the jackets communicated respectively with the these zones may be connected to each other in series, it is satisfactory to provide only one circulation pump and only one refrigerant tank in the cooling device.

Although the explanation has been made of the embodiments in which two CPUs are cooled, there may be similarly configured a cooling device in the case of cooling a larger number of CPUs. That is, with the provision of a radiator in which liquid channels are grouped into zones in the same number as that of the CPUs, and jackets in the same number as that of the CPUS, the respective zones of the liquid channels are alternately connected to the respective jackets so as to constitute a series circulation passage in which a single pump or a plurality pumps are used for circulating the liquid refrigerant.

Further, although explanation has been made of the embodiment in which the liquid channels of the single radiator are grouped into a plurality of zones, there may be provided a plurality of radiators each having liquid channels in a single zone, which are alternately connected with a plurality of jackets so as to constitute a series circulation passage as stated above. Even this configuration may exhibit technical effects and advantages similar to those explained above.

It should be further understood by those skilled in the art that although the foregoing description has been made on embodiments of the invention, the invention is not limited thereto and various changes and modifications may be made without departing from the spirit of the invention and the scope of the appended claims.

1. A heat receiving jacket in a liquid cooling device for electronic equipment, for transferring a heat from a heating portion in the electronic equipment, comprising:
a fin piece formed from a high heat conductive member, having a base portion formed thereon with a plurality of thin fins which are arranged in parallel and rise up from one surface of the base portion, and
a casing accommodating therein the fin piece at its center part so that liquid refrigerant flows between the thin fins, and comprising header portions provided on an inlet side and an outlet side of the thin fins through which the liquid refrigerant flows, and defining therein spaces for causing the liquid refrigerant to branch and merge, and inlet port and outlet port for the liquid refrigerant, formed in side parts thereof corresponding to the head portions.

2. A heart receiving jacket as set forth in claim 1, wherein the casing have a cut recess for receiving the fin piece, and the fin piece has a width in the flowing direction of the liquid refrigerant, which is larger that of the header portions in the flowing direction.

3. A heat receiving jacket as set forth in claim 1, wherein the thin fins are formed by carving in relief the fin piece, and are integrally incorporated with the base portion of the fin piece.

4. A heat receiving jacket as set forth in claim 1, wherein the thin fins have such a shape that they rise up from the base portion of the fin piece, being curved, and tip ends of the thin fins are displaced in a direction perpendicular to the base portion so that tip ends of the thin fins are thermally connected to the interior of the casing.

5. A heat receiving jacket as set forth in claim 4, wherein the height of the thin pieces in a direction in which the thin pieces rises up being curved, is higher than the accommodating part of the casing which accommodates the fin piece.

6. A heat receiving jacket as set forth in claim 1, wherein the base portion of the fin piece has a flange part so that the base portion serves as a cover portion for the casing which accommodates therein the fin piece.

7. A heat receiving jacket as set forth in claim 6, wherein the base portion of the fin piece is thermally connected thereto with the heating portion of the electronic equipment, at a surface thereof opposite to the one surface where the thin fins are formed.

8. A heat receiving jacket as set forth in claim 6, further comprising:
a cover member having an opening in its center part, wherein the fin piece is accommodated in an accommodation space defined by the casing and the cover member, and the base portion of the fin piece is thermally connected thereto with the heating portion of the electronic equipment at a surface thereof which is opposite to the one surface where the thin fins are formed, through the opening of the cover member.

9. A heat receiving jacket as set forth in claim 1, wherein the thin fins have such a shape that they rise up from the base portion of the fin piece being curved, and tip ends of the thin fins are displaced in a direction perpendicular to the base portion so as to be thermally connected to the inner surface of the casing.

10. A heat receiving jacket as set forth in claim 9, wherein the thin fins have a height in a direction in which the thin fins rise up being curved, is higher than the accommodating part of the casing which accommodates the fin piece.

11. A heat receiving jacket in a liquid cooling device for electronic equipment, for transferring a heating part of the electronic equipment to liquid refrigerant, comprising:
two fin pieces each formed from a high heat conductive member, and composed of a base portion, and thin fins which rise up from one surface of the base portion, in parallel, being curved, and,
a casing accommodating therein with the fin pieces so as to cause the liquid refrigerant to flow between the thin fins, and comprising a first header portion defining therein a space for causing the liquid refrigerant to branch, on the inlet side of one of the fin piece in which the liquid refrigerant flows between the thin fins, a second header portion defining there in space for merging the liquid refrigerant on the outlet side of the other one of the fin pieces, a third header portion for allowing the liquid refrigerant to flow from the one to the other of the fin pieces, provided on the side opposed to the first and second harder portion across the two pieces therebetween, and an inlet port and an outlet port for the liquid refrigerant formed on one side part of the casing which correspond to the first and second header portion.

12. A liquid cooling device for radiating a heat generated from a heating member used in electronic equipment and transferred by liquid refrigerant, comprising:
a plurality of heat receiving jackets each having therein a channel for the liquid refrigerant, for transferring the heat generated from the heating member to the liquid refrigerant flowing from an inlet port, for discharging the liquid refrigerant from an outlet port,
a plurality of heat radiating portions each having therein a plurality of channels for the liquid refrigerant, for cooling the liquid refrigerant flowing from an inlet port, and discharging the liquid refrigerant from an outlet port,
a circulation pump for driving the liquid refrigerant,
a fan for cooling the plurality of radiators, and
pipe lines alternately connecting the heat receiving jackets with the heat radiating portions so as to define a passage for the liquid refrigerant, a part of the pipe lines being connected thereto with the pump so as to constitute a single closed circulation passage for the liquid refrigerant.

13. A cooling device as set forth in claim 12, wherein the plurality of heat receiving jackets consisting of a first heat receiving jacket and a second heat receiving jacket, an the plurality of heat radiating portions constituting a radiator and consisting of a first heart radiating portion and a second heat radiating portion integrally incorporated with one another, the first and second heat radiating portions being arranged with their outlet ports being located in the center part of the radiator and with their inlet ports being located in end portions of the radiator.
